(19) United States
(12) Patent Application Publication
(10) Pub. No.: US 2023/0369402 A1
(43) Pub. Date: Nov. 16, 2023

(54) SEMICONDUCTOR DEVICES WITH ASYMMETRIC SOURCE/DRAIN DESIGN

(71) Applicant: Taiwan Semiconductor Manufacturing Co., Ltd., Hsinchu (TW)

(72) Inventors: Chih-Ching WANG, Jinhu Township (TW); Wen-Hsing HSIEH, Hsinchu City (TW)

(73) Assignee: Taiwan Semiconductor Manufacturing Co., Ltd., Hsinchu (TW)

(21) Appl. No.: 18/181,085

(22) Filed: Mar. 9, 2023

Related U.S. Application Data
(60) Provisional application No. 63/374,782, filed on Sep. 7, 2022.
(60) Provisional application No. 63/340,274, filed on May 10, 2022.

(51) Int. Cl. H01L 29/08; H01L 29/06; H01L 29/423; H01L 29/775; H01L 29/66

(52) U.S. Cl. CPC H01L 29/0847; H01L 29/0673; H01L 29/42392; H01L 29/775; H01L 29/66545; H01L 29/66553; H01L 29/66439

(57) ABSTRACT

The present disclosure describes a semiconductor device having an asymmetric source/drain (S/D) design. The semiconductor device includes multiple semiconductor layers on a substrate, a gate structure wrapped around the multiple semiconductor layers, an inner spacer structure between the multiple semiconductor layers and in contact with a first side of the gate structure, and an epitaxial layer in contact with a second side of the gate structure. The second side is opposite to the first side.

### CROSS-REFERENCE TO RELATED APPLICATIONS

This application claims the benefit of U.S. Provisional Patent Application No. 63/374,782, titled “Semiconductor Devices with Asymmetric Source/Drain Design,” filed Sep. 7, 2022, and U.S. Provisional Patent Application No. 63/340,274, titled “Strategic Asymmetric SD Design for GAA Performance Enhancement,” filed May 10, 2022, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of defects control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having an asymmetric source/drain (S/D) design, in accordance with some embodiments.

FIG. 2 illustrates a cross-sectional view of a semiconductor device having an asymmetric S/D design, in accordance with some embodiments.

FIG. 3 is a flow diagram of a method for fabricating a semiconductor device having an asymmetric S/D design, in accordance with some embodiments.

FIGS. 4-17 illustrate cross-sectional views of a semiconductor device having an asymmetric S/D design, in accordance with some embodiments.

FIGS. 18-22 illustrate cross-sectional views of a semiconductor device having another asymmetric S/D design, in accordance with some embodiments.

FIGS. 23-27 illustrate cross-sectional views of a semiconductor device having yet another asymmetric S/D design, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With advances in semiconductor technology, multi-gate devices have been introduced to improve gate control by increasing gate-channel coupling, reducing off-state current, and reducing short-channel effects (SCEs). One such multi-gate device is the nanostructure transistor, which includes the gate-all-around field effect transistor (GAA FET), the nanosheet transistor, the nanowire transistor, the multi bridge channel transistor, the nano-ribbon transistor, and other similar structured transistors. The nanostructure transistor provides a channel in a stacked nanosheet/nanowire configuration. The GAA FET device derives its name from the gate structure that can extend around the channel and provide gate control of the channel on multiple sides of the channel. Nanostructure transistor devices are compatible with MOSFET manufacturing processes and their structure allows them to be scaled while maintaining gate control and mitigating SCEs.

With increasing demand for lower power consumption, higher performance, and smaller area (collectively referred to as “PPA”) of semiconductor devices, nanostructure transistor devices can have their challenges. For example, nanostructure transistor devices can have inner spacer structures between the gate structure and the source/drain (S/D) structures to reduce parasitic capacitance. In p-type nanostructure transistor devices, embedded silicon germanium (SiGe) stressors (e.g., S/D structures) can be used to increase the device current and improve device performance. However, dislocation defects can form in the S/D structures of nanostructure transistor devices having inner spacer structures. The S/D defects can relax the strain imparted on the channels, lower the device current, and degrade the device performance of nanostructure transistor devices. At the same time, without the inner spacer structures, the dislocation defects in the S/D structures can be reduced while the parasitic capacitance between the S/D structures and the gate structure can increase. The increase of parasitic capacitance can decrease the device performance.

Various embodiments in the present disclosure provide example methods for forming an asymmetric source/drain (S/D) design for a nanostructure transistor device (e.g., a GAA FET) and/or other semiconductor devices in an integrated circuit (IC). The nanostructure transistor device can have multiple nanostructure channels and a gate structure wrapped around the nanostructure channels. An inner spacer structure can be in contact with a first side of the gate structure and can be disposed between the gate structure and a first S/D structure. An epitaxial layer can be in contact with a second side of the gate structure and can be disposed between the gate structure and a second S/D structure. The second side can be opposite to the first side. In some embodiments, the first side can be a drain side of the nanostructure transistor device and the second side can be a source side of the nanostructure transistor device.

With the epitaxial layer on the source side, the dislocation defects in the second S/D structure can be reduced by about 50% to about 80%, the resistance of the second S/D structure can be significantly reduced, the proximity between the second S/D structure and the gate structure can be reduced, the strain imparted on the nanostructure channels can be improved, and the device current can be increased. The inner spacer structure on the drain side can reduce the parasitic capacitance between the gate structure and the first S/D structure. As the channel current of the nanostructure transistor device is dominated by the resistance of the second S/D structure on the source side, the asymmetric design of the nanostructure transistor device can improve the device performance, for example, by about 5% to about 20% for a p-type nanostructure transistor device and by about 0.5% to about 5% for an n-type nanostructure transistor device.

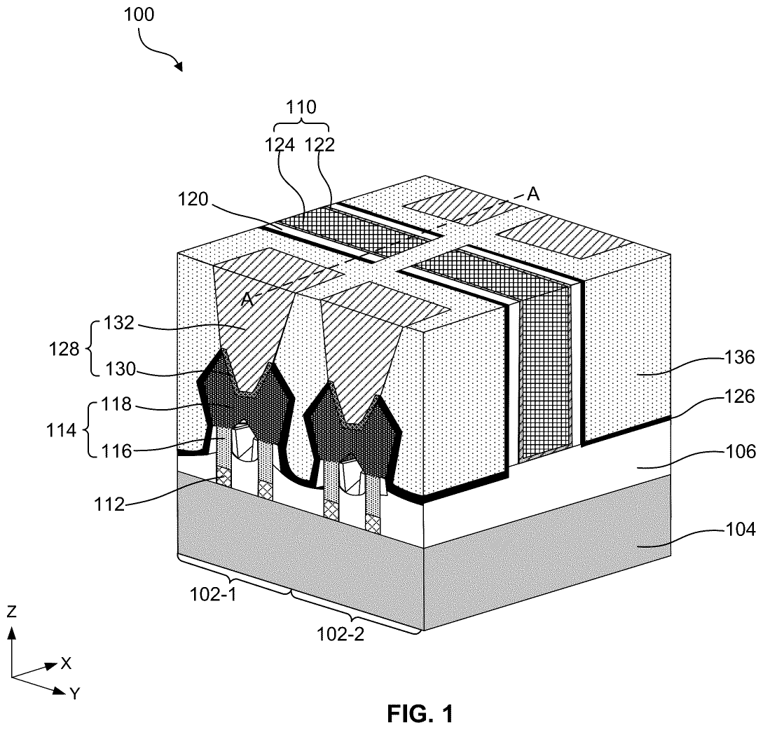

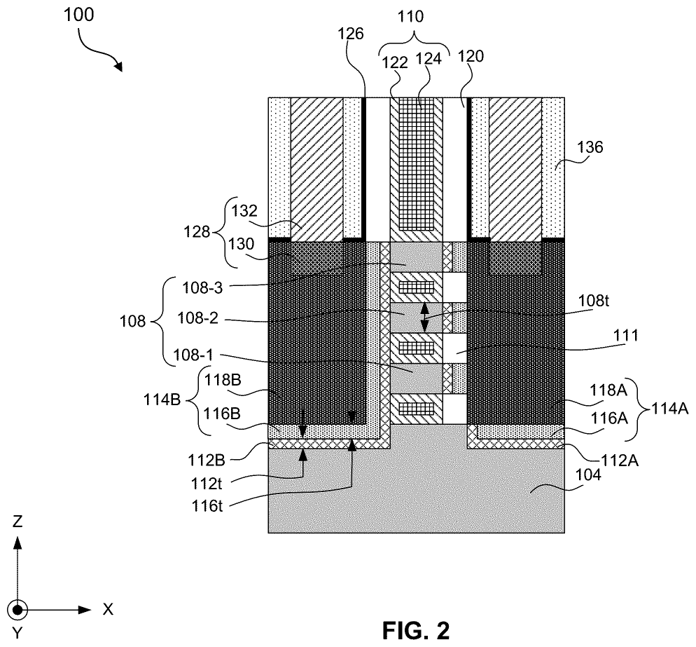

FIG. 1 illustrates an isometric view of a semiconductor device 100 having an asymmetric S/D design, in accordance with some embodiments. FIG. 2 illustrates a cross-sectional view of semiconductor device 100 along line A-A shown in FIG. 1, in accordance with some embodiments. Semiconductor device 100 can include nanostructure transistors 102-1 and 102-2. Referring to FIGS. 1 and 2, semiconductor device 100 having nanostructure transistors 102-1 and 102-2 can be formed on a substrate 104 and can be isolated by shallow trench isolation (STI) regions 106. Each of nanostructure transistors 102-1 and 102-2 can include nanostructures 108, gate structures 110, gate spacers 120, inner spacer structures 111, epitaxial layers 112A and 112B (collectively referred to as “epitaxial layers 112”), S/D structures 114A and 114B (collectively referred to as “S/D structures 114”), etch stop layer (ESL) 126, interlayer dielectric (ILD) layer 136, and S/D contact structures 128.

In some embodiments, nanostructure transistors 102-1 and 102-2 can be both n-type nanostructure transistors (NFETs). In some embodiments, nanostructure transistor 102-1 can be an NFET and have n-type S/D structures 114. Nanostructure transistor 102-2 can be a p-type nanostructure transistor (PFET) and have p-type S/D structures 114. In some embodiments, nanostructure transistors 102-1 and 102-2 can be both PFETs. Though FIG. 1 shows two nanostructure transistors, semiconductor device 100 can have any number of nanostructure transistors. In addition, semiconductor device 100 can be incorporated into an IC through the use of other structural components, such as conductive vias, conductive lines, dielectric layers, passivation layers, and interconnects, which are not shown for simplicity. The discussion of elements of nanostructure transistors 102-1 and 102-2 with the same annotations applies to each other, unless mentioned otherwise. And like reference numerals generally indicate identical, functionally similar, and/or structurally similar elements.

Referring to FIGS. 1 and 2, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between nanostructure transistors 102-1 and 102-2 from each other and from neighboring nanostructure transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, nanostructures 108 can be formed on patterned portions of substrate 104. Embodiments of the nanostructures disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures.

As shown in FIG. 2, nanostructures 108 can extend along an X-axis and through nanostructure transistors 102-1 and 102-2. In some embodiments, nanostructures 108 can be disposed on substrate 104 and can include a stack of semiconductor layers 108-1, 108-2, and 108-3 (also collectively referred to as “semiconductor layers 108”), which can be in the form of nanostructures, such as nanosheets, nanowires, and nano-ribbons. Each of nanostructures 108 can form a channel region underlying gate structures 110 of nanostructure transistors 102-1 and 102-2. In some embodiments, nanostructures 108 can include semiconductor materials similar to or different from substrate 104. In some embodiments, each of nanostructures 108 can include silicon. In some embodiments, each of nanostructures 108 can include silicon germanium. The semiconductor materials of nanostructures 108 can be undoped or can be in-situ doped during their epitaxial growth process. Each of nanostructures 108 can have a thickness 108t along a Z-axis ranging from about 5 nm to about 15 nm. As shown in FIGS. 1 and 2, nanostructures 108 under gate structures 110 can form channel regions of semiconductor device 100 and represent current carrying structures of semiconductor device 100. Though three layers of nanostructures 108 are shown in FIG. 2, nanostructure transistors 102-1 and 102-2 can have any number of nanostructures 108.

Referring to FIGS. 1 and 2, gate structures 110 can be multi-layered structures and can wrap around middle portions of nanostructures 108. In some embodiments, each of nanostructures 108 can be wrapped around by one or more layers of gate structures 110, in which gate structures 110 can be referred to as “gate-all-around (GAA) structures” and nanostructure transistors 102-1 and 102-2 can also be referred to as “GAA FETs 102-1 and 102-2.”

As shown in FIG. 2, gate structures 110 can include a gate dielectric layer 122 and a metal gate structure 124. In some embodiments, gate dielectric layer 122 can include an interfacial layer and a high-k dielectric layer. In some embodiments, gate dielectric layer 122 can include a high-k dielectric layer. The term “high-k” can refer to a high dielectric constant. In the field of semiconductor device structures and manufacturing processes, high-k can refer to a dielectric constant that is greater than the dielectric constant of SiO₂ (e.g., greater than about 3.9). In some embodiments, the interfacial layer can include silicon oxide formed by a deposition process or an oxidation process. In some embodiments, the high-k dielectric layer can include hafnium oxide (HfO₂), zirconium oxide (ZrO₂), and other suitable high-k dielectric materials. As shown in FIG. 2, gate dielectric layer 122 can wrap around each of nanostructures 108, and thus electrically isolate nanostructures 108 from each other and from conductive metal gate structure 124 to prevent shorting between gate structures 110 and nanostructures 108 during operation of nanostructure transistors 102-1 and 102-2. In some embodiments, gate dielectric layer 122 can have a thickness along a Z-axis ranging from about 10 Å to about 50 Å.

In some embodiments, metal gate structure 124 can include a work-function layer and a gate electrode. The work-function layer can wrap around nanostructures 108 and can include work-function metals to tune the threshold voltage (Vₜ) of nanostructure transistors 102-1 and 102-2. In some embodiments, the work-function layer can include titanium nitride, ruthenium, titanium aluminum, titanium aluminum carbon, tantalum aluminum, tantalum aluminum carbon, or other suitable work-function metals. In some embodiments, the work-function layer can include a single metal layer or a stack of metal layers. The stack of metal layers can include work-function metals having work-function values equal to or different from each other. The gate electrode can include titanium, tantalum, aluminum, cobalt, tungsten, nickel, ruthenium, and other suitable conductive materials. Depending on the spaces between adjacent nanostructures 108 and the thicknesses of the layers of gate structures 110, nanostructures 108 can be wrapped around by one or more layers of gate structures 110 filling the spaces between adjacent nanostructures 108.

Referring to FIGS. 1 and 2, gate spacers 120 can be disposed on sidewalls of gate structures 110 and in contact with gate dielectric layer 122. Inner spacer structures 111 can be disposed adjacent to one end portions of nanostructures 108 and between S/D structure 114A and gate structures 110, according to some embodiments. Gate spacers 120 and inner spacer structures 111 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 120 and inner spacer structures 111 can include the same insulating material. In some embodiments, gate spacers 120 and inner spacer structures 111 can include different insulating materials. Gate spacers 120 and inner spacer structures 111 can include a single layer or a stack of insulating layers. In some embodiments, gate spacers 120 and inner spacer structures 111 can have a low-k material with a dielectric constant less than about 3.9 (e.g., about 3.5, about 3.0, or about 2.8). In some embodiments, inner spacer structures 111 can have a thickness along an X-axis ranging from about 4 nm to about 8 nm.

S/D structures 114 can be disposed on substrate 104 and on opposing sides of nanostructures 108. In some embodiments, semiconductor device 100 can have a first S/D structure 114A on a first side (e.g., drain side) and a second S/D structure 114B on a second side (e.g., source side) of nanostructure transistors 102-1 or 102-2. S/D structures 114 can function as S/D regions of nanostructure transistors 102-1 or 102-2. In some embodiments, S/D structures 114 can have any geometric shape, such as a polygon, an ellipsis, and a circle. In some embodiments, S/D structures 114 can include an epitaxially-grown semiconductor material, such as silicon, the same material as substrate 104. In some embodiments, the epitaxially-grown semiconductor material can include an epitaxially-grown semiconductor material different from the material of substrate 104, such as silicon germanium, and imparts a strain on the channel regions under gate structures 110. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 114 can include silicon and can be in-situ doped during an epitaxial growth process using n-type dopants, such as phosphorus and arsenic. In some embodiments, S/D structures 114 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 114 can include one or more epitaxial layers, where each epitaxial layer can have different compositions.

As shown in FIG. 2, S/D structures 114 can include first S/D epitaxial layers 116A and 116B (collectively referred to as “first S/D epitaxial layers 116”) and second S/D epitaxial layers 118A and 118B (collectively referred to as “second S/D epitaxial layers 118”). In some embodiments, n-type S/D structures 114 can include arsenide or phosphide doped silicon. For example, first S/D epitaxial layers 116 can include silicon doped with arsenide or phosphide at a concentration from about 1×10¹⁹ atoms/cm³ to about 1×10²¹ atoms/cm³. Second S/D epitaxial layers 118 can include silicon doped with phosphide at a concentration from about 1×10²¹ atoms/cm³ to about 1×10²² atoms/cm³. In some embodiments, p-type S/D structures 114 can include boron doped silicon germanium. In some embodiments, first S/D epitaxial layers 116 can have a lower Ge concentration than second S/D epitaxial layers 118 to prevent lattice mismatch and dislocation defects. For example, first S/D epitaxial layers 116 can include silicon germanium having a germanium concentration from about 0 to about 30% and doped with boron at a concentration from about 1×10²⁰ atoms/cm³ to about 1×10²¹ atoms/cm³. Second S/D epitaxial layers 118 can include silicon germanium having a germanium concentration from about 20% to about 100% and doped with boron at a concentration from about 1×10²¹ atoms/cm³ to about 2×10²¹ atoms/cm³.

In some embodiments, first S/D epitaxial layers 116 can have a thickness 116t ranging from about 2 nm to about 10 nm. If thickness 116t is less than about 2 nm, first epitaxial layers 116 may not grow. If thickness 116t is greater than about 10 nm, the proximity between S/D structure 114 and gate structures 110 may increase and the device on-current of nanostructure transistors 102-1 and 102-2 may decrease. In some embodiments, sidewalls of first S/D epitaxial layers 116A and inner spacer structures 111 can be aligned. In some embodiments, sidewalls of first S/D epitaxial layers 116A and inner spacer structures 111 may not be aligned.

As shown in FIG. 2, epitaxial layers 112 can be disposed between nanostructures 108 and S/D structures 114. In some embodiments, inner spacer structures 111 can be in contact with gate structures 110 at a first side (e.g., drain side) and epitaxial layer 112B can be in contact with gate structures 110 at a second side (e.g., source side) of nanostructure transistors 102-1 and 102-2. In some embodiments, epitaxial layer 112A can be uniformly disposed on the end portions of semiconductor layers 108-1, 108-2, and 108-3 and substrate 104 at the first side. In some embodiments, as shown in FIG. 2, epitaxial layer 112A can include a vertical portion in contact with nanostructures 108 and a horizontal portion in contact with substrate 104. In some embodiments, epitaxial layer 112B can be uniformly disposed on gate structures 110, nanostructures 108, and substrate 104 at the second side. The second side can be opposite to the first side. In some embodiments, as shown in FIG. 2, epitaxial layer 112B can include a vertical portion in contact with gate structures 110 and nanostructures 108 and a horizontal portion in contact with substrate 104. In some embodiments, as shown in FIG. 2, epitaxial layers 112A and 112B can be formed on both ends of nanostructures 108 and on one side (e.g., source side) of gate structures 110. In some embodiments, epitaxial layers 112A and 112B are not formed on the other side (e.g., drain side) of gate structures 110. As semiconductor device 100 has structures on the source side different from the structures on the drain side, for example, inner spacer structures 111 in contact with gate structures 110 on the drain side and epitaxial layer 112B in contact with gate structures 110 on the source side, this S/D design of semiconductor device 100 can be referred to as “an asymmetric S/D design.”

In some embodiments, epitaxial layers 112 can include an epitaxially-grown semiconductor material, such as silicon. Epitaxial layers 112 can be un-doped or doped. In some embodiments, epitaxial layers 112 can include un-doped silicon. In some embodiments, epitaxial layers 112 can include silicon and can be in-situ doped during an epitaxial growth process using n-type dopants, such as phosphorus and arsenic. The n-type dopants can have a concentration from about 1×10¹⁹ atoms/cm³ to about 1×10²¹ atoms/cm³. In some embodiments, epitaxial layers 112 can include silicon and can be in-situ doped during an epitaxial growth process using p-type dopants, such as boron. The p-type dopants can have a concentration from about 1×10¹⁹ atoms/cm³ to about 1×10²¹ atoms/cm³. If the concentration of the n-type dopant or the p-type dopant is greater than about 1×10²¹ atoms/cm³, the hot carrier leakage current of nanostructure transistors 102-1 and 102-2 may increase. If the concentration of the n-type dopant or the p-type dopant is less than about 1×10¹⁹ atoms/cm³, the device on-current of nanostructure transistors 102-1 and 102-2 may decrease.

In some embodiments, epitaxial layers 112 can act as an etch stop layer to protect S/D structures 114 during the formation of gate structures 110. In some embodiments, epitaxial layers 112 can reduce the dislocation defects in S/D structure 114B by about 50% to about 80%, reduce the resistance of S/D structure 114B, reduce the proximity between S/D structure 114B and gate structures 110, increase the strain imparted on nanostructures 108, and increase the device on-current of nanostructure transistors 102-1 and 102-2.

In some embodiments, epitaxial layers 112 can have a thickness 112t ranging from about 1 nm to about 10 nm. A ratio of thickness 112t to thickness 108t can range from about 0.1 to about 2. If thickness 112t is less than about 1 nm or the ratio is less than about 0.1, first epitaxial layers 116B may not grow and S/D structure 114B may be damaged during the formation of gate structures 110. If thickness 112t is greater than about 10 nm or the ratio is greater than about 2, the proximity between S/D structure 114B and gate structures 110 may increase and the device on-current of nanostructure transistors 102-1 and 102-2 may decrease.

In some embodiments, epitaxial layers 112 can improve the device performance for a p-type nanostructure transistor device by about 5% to about 20%. In some embodiments, epitaxial layers 112 can improve the device performance for an n-type nanostructure transistor device by about 0.5% to about 5%.

Referring to FIGS. 1 and 2, ESL 126 can be disposed on STI regions 106, S/D structures 114, and sidewalls of gate spacers 120. ESL 126 can be configured to protect STI regions 106, S/D structures 114, and gate structures 110 during the formation of S/D contact structures on S/D structures 114. In some embodiments, ESL 126 can include, for example, silicon oxide, silicon nitride, silicon oxynitride, silicon carbide, silicon carbonitride, boron nitride, silicon boron nitride, silicon carbon boron nitride, or a combination thereof.

ILD layer 136 can be disposed on ESL 126 over S/D structures 114 and STI regions 106. ILD layer 136 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

S/D contact structures 128 can be disposed on S/D structures 114 and can be configured to electrically connect S/D regions (e.g., S/D structures 114) of nanostructure transistors 102-1 and 102-2 to other elements of semiconductor device 100 and/or other semiconductor devices in the IC of semiconductor device 100. S/D contact structures 128 can be formed within ILD layer 136. According to some embodiments, S/D contact structures 128 can include metal silicide layers 130 and metal contacts 132 disposed on metal silicide layers 130. Examples of metal used for forming metal silicide layers 130 can include cobalt, titanium, and nickel. In some embodiments, metal contacts 132 can include, for example, tungsten, cobalt, aluminum, copper, titanium, tantalum, silver, ruthenium, metal alloys, or combinations thereof.

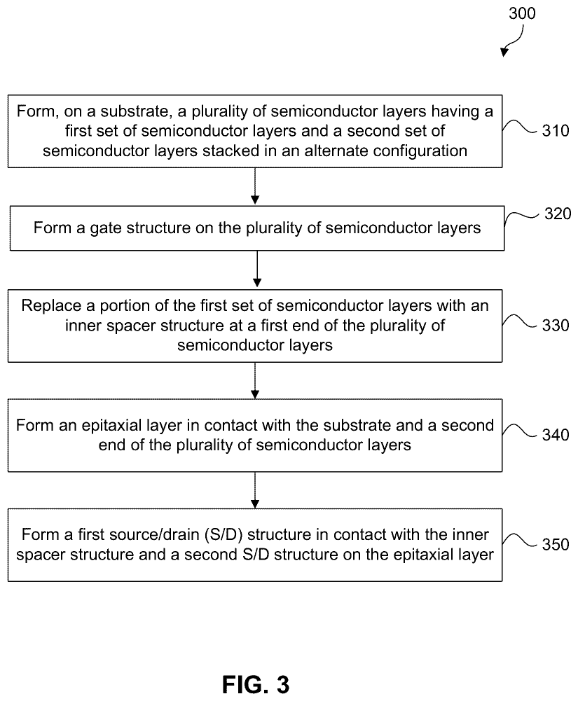

FIG. 3 is a flow diagram of a method 300 for fabricating semiconductor device 100 having an asymmetric S/D design, in accordance with some embodiments. Method 300 may not be limited to nanostructure transistor devices and can be applicable to other devices that would benefit from the asymmetric S/D design. Additional fabrication operations may be performed between various operations of method 300 and may be omitted merely for clarity and ease of description. Additional processes can be provided before, during, and/or after method 300; one or more of these additional processes are briefly described herein. Moreover, not all operations may be needed to perform the disclosure provided herein. Additionally, some of the operations may be performed simultaneously or in a different order than shown in FIG. 3. In some embodiments, one or more other operations may be performed in addition to or in place of the presently described operations.

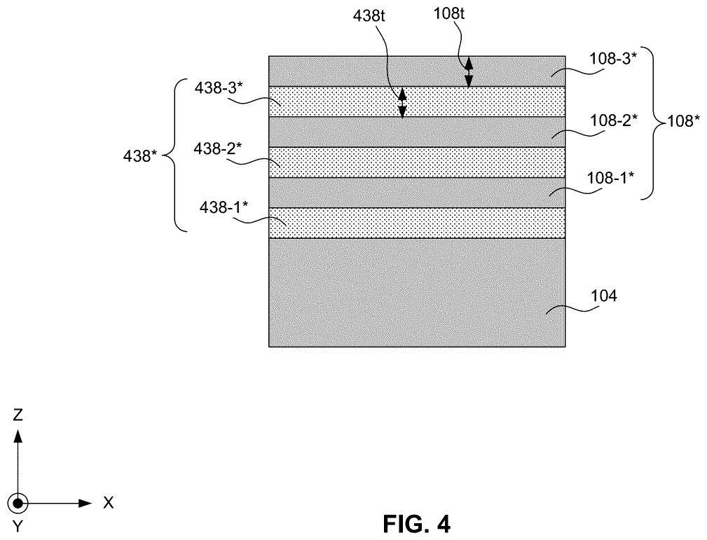

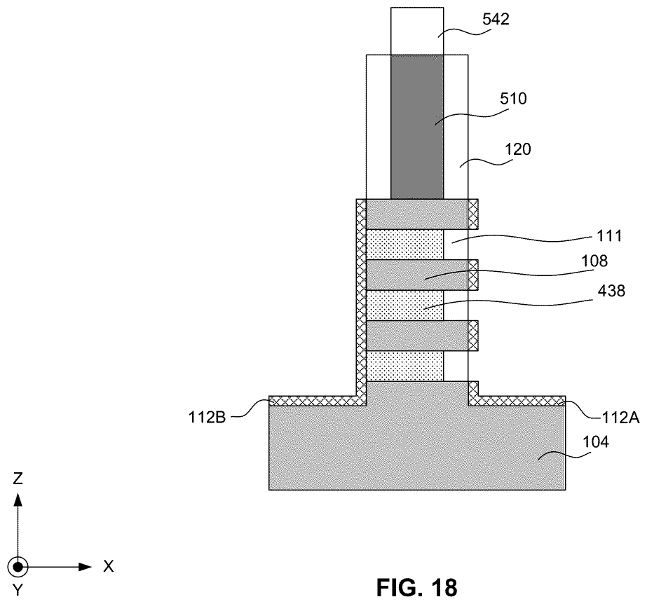

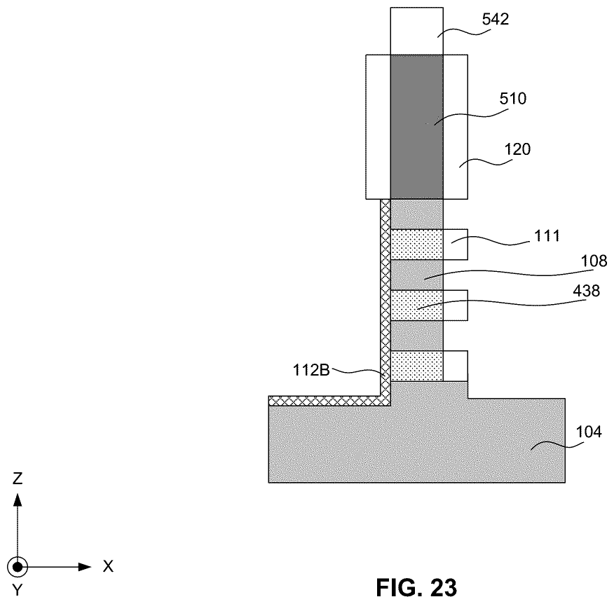

For illustrative purposes, the operations illustrated in FIG. 3 will be described with reference to the example fabrication process for fabricating semiconductor device 100 as illustrated in FIGS. 4-27. FIGS. 4-27 illustrate cross-sectional views of semiconductor device 100 having asymmetric S/D designs at various stages of its fabrication, in accordance with some embodiments. In some embodiments, FIGS. 4-17 illustrate cross-sectional views of semiconductor device 100 having a first asymmetric S/D design. In some embodiments, FIGS. 18-22 illustrate cross-sectional views of semiconductor device 100 having a second asymmetric S/D design. In some embodiments, FIGS. 23-27 illustrate cross-sectional views of semiconductor device 100 having a third asymmetric S/D design. Elements in FIGS. 4-27 with the same annotations as elements in FIGS. 1 and 2 are described above.

In referring to FIG. 3, method 300 begins with operation 310 and the process of forming, on a substrate, multiple semiconductor layers having a first set of semiconductor layers and a second set of semiconductor layers stacked in an alternate configuration. For example, as shown in FIG. 4, first set of semiconductor layers 438-1*, 438-2*, and 438-3* (collectively referred to as “first set of semiconductor layers 438*”) and second set of semiconductor layers 108-1*, 108-2*, and 108-3* (collectively referred to as “second set of semiconductor layers 108*”) can be formed on substrate 104. First and second sets of semiconductor layers 438* and 108* can be stacked in an alternate configuration.

In some embodiments, first and second sets of semiconductor layers 438* and 108* can be epitaxially grown on substrate 104. In some embodiments, first set of semiconductor layers 438* can include a semiconductor material different from substrate 104. Second set of semiconductor layers 108 can include a semiconductor material the same as substrate 104. In some embodiments, substrate 104 and second set of semiconductor layers 108* can include silicon. First set of semiconductor layers 438* can include silicon germanium. In some embodiments, a germanium concentration in the silicon germanium can range from about 10% to about 50% to increase etch selectivity between first and second sets of semiconductor layers 438* and 108*. In some embodiments, first set of semiconductor layers 438* can have a thickness 438t along a Z-axis ranging from about 3 nm to about 10 nm. Second set of semiconductor layers 108* can have a thickness 108t along a Z-axis ranging from about 5 nm to about 15 nm.

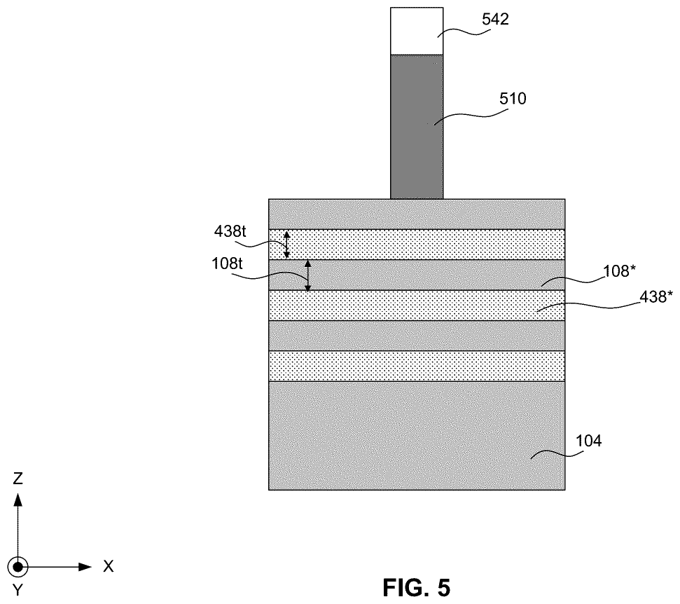

Referring to FIG. 3, in operation 320, a gate structure is formed on the plurality of semiconductor layers. For example, as shown in FIGS. 5-7, sacrificial gate structures 510 can be formed on semiconductor layers 438 and 108. In some embodiments, operation 320 can include formation of sacrificial gate structures 510 and gate capping structure 542, formation of gate spacers 120, and S/D region recess. Referring to FIG. 5, in some embodiments, sacrificial gate structures 510 can be formed by a blanket deposition of amorphous silicon or polysilicon and a hard mask layer followed by photolithography to form gate capping structure 542 and etching of the deposited amorphous silicon or polysilicon not protected by gate capping structure 542. In some embodiments, gate capping structure 542 can include silicon nitride, silicon oxynitride, silicon carbide, silicon carbonitride, or other suitable dielectric materials.

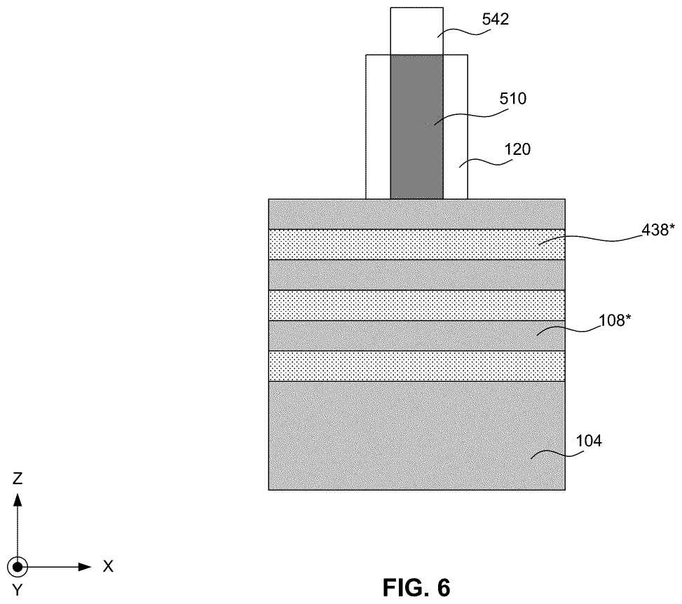

In some embodiments, as shown in FIG. 6, gate spacers 120 can be formed by a blanket deposition of a dielectric material followed by a directional etch to keep the dielectric material on sidewall surfaces of sacrificial gate structures 510. In some embodiments, the dielectric material can include silicon oxide, silicon nitride, silicon oxynitride, silicon carbonitride, silicon oxycarbide, silicon oxycarbonitride, a low-k material, and a combination thereof.

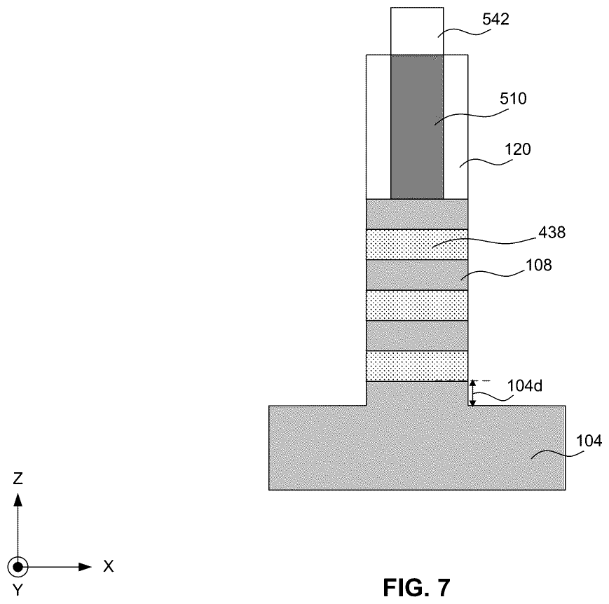

In some embodiments, as shown in FIG. 7, semiconductor layers 438* and 108* and substrate 104 can be recessed to form S/D regions of nanostructure transistors 102-1 and 102-2. The S/D region recess can include a dry etch process performed at a temperature from about 40° C. to about 70° C. The dry etch process can be biased at a voltage from about 300 V to about 600 V. In some embodiments, the dry etch process can etch a portion of the first and second sets of semiconductor layers 438* and 108* and can extend into substrate 104, as shown in FIG. 7. In some embodiments, the dry etch process can extend into substrate by a distance 104d along a Z-axis ranging from about 5 nm to about 20 nm. After the S/D region recess, end portions of first and second semiconductor layers 438 and 108 can be exposed for subsequent processes.

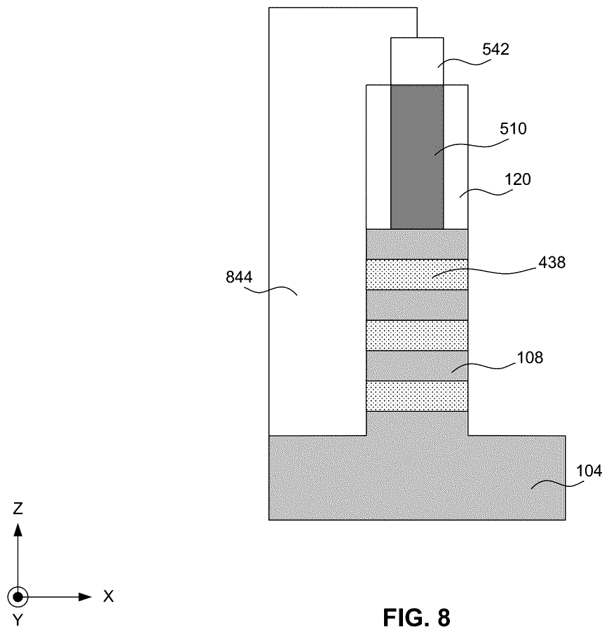

Referring to FIG. 3, in operation 330, a portion of the first set of semiconductor layers is replaced with an inner spacer structure at a first end of the multiple semiconductor layers. For example, as shown in FIGS. 8-11, a portion of first set of semiconductor layers 438 is replaced with inner spacer structures 111 at a first end of semiconductor layers 438 and 108. The replacement of the portion of first set of semiconductor layers 438 with inner spacer structures 111 can include covering the second end of semiconductor layers 438 and 108, laterally recessing the portion of first set of semiconductor layers 438, and forming inner spacer structures 111 at the recess of first set of semiconductor layers 438 between the second set of semiconductor layers 108.

Referring to FIG. 8, a mask layer 844 can be patterned to cover the second end of semiconductor layers 438 and 108. Composition of the mask layer 844 can include a photoresist, a bottom anti-reflection coating, a hard mask, and/or other suitable materials. The patterning process can include forming mask layer 844 over the structure shown in FIG. 7, exposing the photoresist to a pattern, performing post-exposure bake processes, and developing the photoresist to form a masking element. Mask layer 844 can be used to protect the second end of semiconductor layers 438 and 108 while one or more etching processes can laterally recess the exposed first end of first set of semiconductor layers 438.

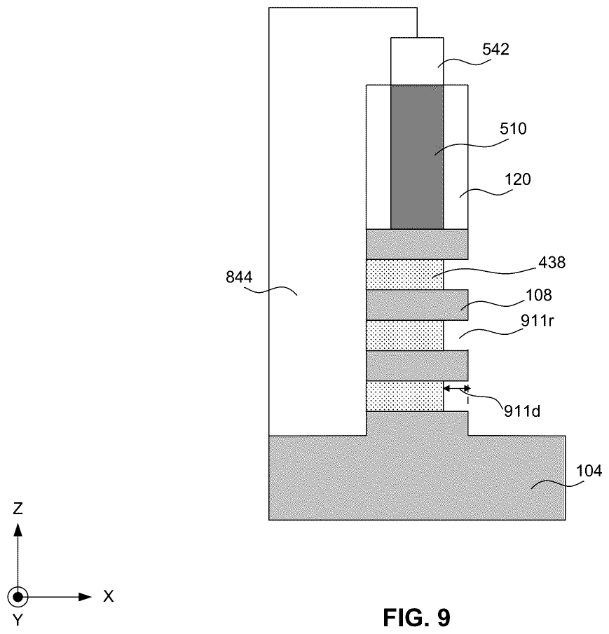

In some embodiments, as shown in FIG. 9, first set of semiconductor layers 438 can be laterally recessed by a selective etching process, in accordance with some embodiments. The selective etching process can have a high etch selectivity between first set of semiconductor layers 438 and second set of semiconductor layers 108. In some embodiments, the selective etching process can include etchants, such as hydrogen fluoride (HF) and fluorine (F₂) gases, and can be performed at a temperature from about 0° C. to about 40° C. under a pressure from about 100 mTorr to about 1000 mTorr. In some embodiments, the selective etching process can include etchants, such as fluorine radical dissociated from nitrogen trifluoride (NF₃), and can be performed at a temperature from about −10° C. to about 10° C. under a pressure from about 3 mTorr to about 1000 mTorr. After the selective etching process, end portions of first set of semiconductor layers 438 on the first end of semiconductor layers 438 and 108 can be laterally recessed to form a recess 911r with a recess depth 911d ranging from about 5 nm to about 10 nm.

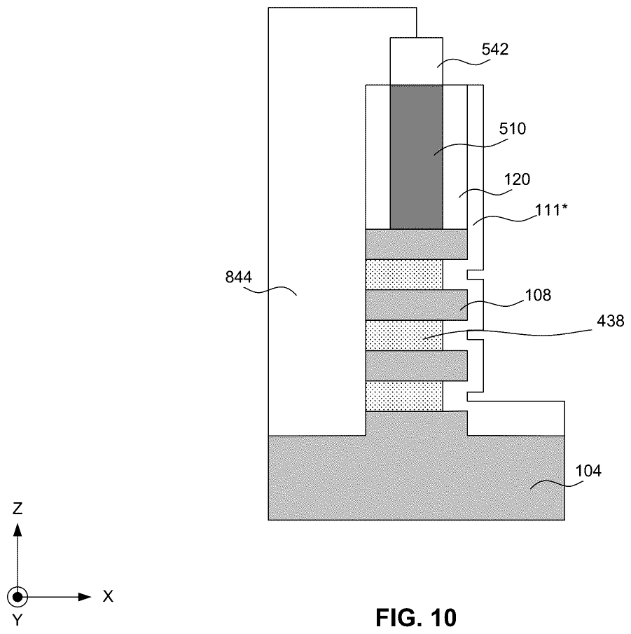

The lateral recess of first set of semiconductor layers 438 can be followed by the formation of inner spacer structures 111. The formation of inner spacer structures 111 can include deposition of spacer layer 111* and trimming spacer layer 111* to form inner spacer structures 111. As shown in FIG. 10, spacer layer 111* can be blanket deposited on gate spacers 120 and the first end of semiconductor layers 438 and 108 by atomic layer deposition (ALD), chemical vapor deposition (CVD), and other suitable deposition methods. In some embodiments, spacer layer 111* can include insulating materials, such as silicon oxide, silicon nitride, silicon oxynitride, silicon carbonitride, silicon oxycarbide, silicon oxycarbonitride, a low-k material, and a combination thereof. In some embodiments, spacer layer 111* can include a single layer or a stack of insulating layers. In some embodiments, spacer layer 111* can fill recess 911r and can have a thickness ranging from about 5 nm to about 10 nm.

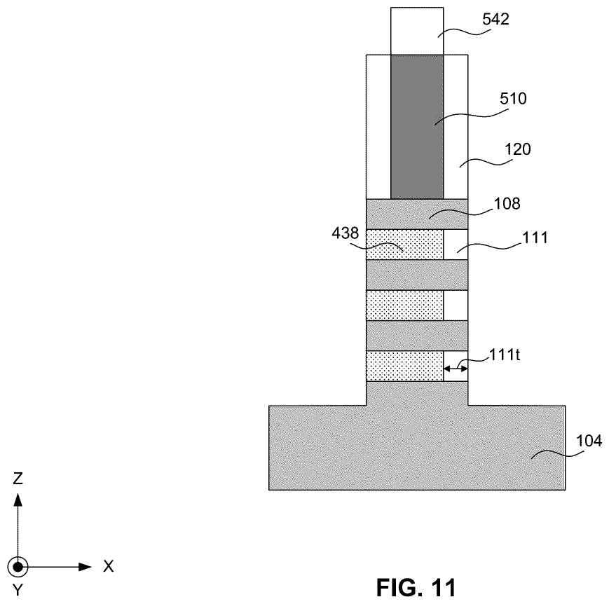

The blanket deposition of spacer layer 111* can be followed by trimming spacer layer 111*. For example, as shown in FIG. 11, spacer layer 111* can be trimmed by a directional etching process to form inner spacer structures 111. The trimming process can remove spacer layer 111* from outside of recess 911r. After the etching process, spacer layer 111* in recess 911r can remain and form inner spacer structures 111. Inner spacer structures 111 can be in contact with the first end of semiconductor layers 438 and 108. In some embodiments, inner spacer structures 111 can have a thickness 111t ranging from about 5 nm to about 10 nm. In some embodiments, end portions of semiconductor layers 108 may be etched during the etching processes of forming inner spacer structures 111. In some embodiments, inner spacer structures 111 can reduce the parasitic capacitance between subsequently-formed S/D structure 114A and gate structures 110. The trimming of spacer layer 111* can be followed by removal of mask layer 844, as shown in FIG. 11.

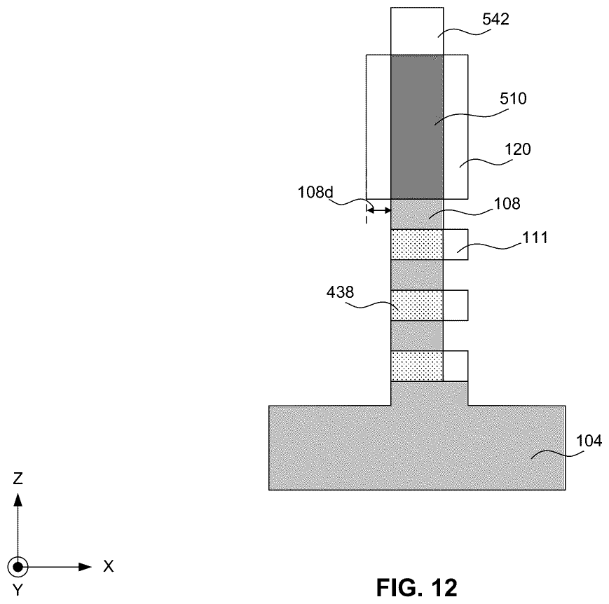

In some embodiments, the formation of inner spacer structures 111 can be followed by laterally etching semiconductor layers 438 and 108, as shown in FIG. 12. In some embodiments, the lateral etch process can have the substantially same or similar etching rate for semiconductor layers 438 and 108. In some embodiments, the lateral etching process can be a dry radial etch and include etchants, such as HF, NF₃, and F₂ gases. In some embodiments, the lateral etching process can be performed at a temperature from about 0° C. to about 200° C. under a pressure from about 0.5 Torr to about 20 Torr to achieve an isotropic etch with substantially same or similar etching rates for semiconductor layers 438 and 108. In some embodiments, semiconductor layers 438 and 108 can be laterally etched by a distance 108d along an X-axis ranging from about 5 nm to about 10 nm. In some embodiments, the first end of first set of semiconductor layers 438 can be protected by inner spacer structures 111 during the lateral etch process. The lateral etch of semiconductor layers 438 and 108 can reduce the proximity between subsequent-formed S/D structure 114B and gate structures 110 and increase the device on-current of nanostructure transistors 102-1 and 102-2.

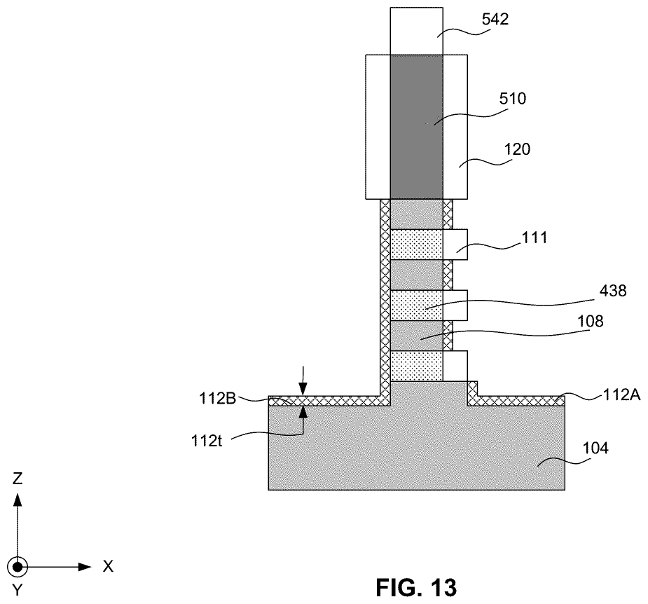

Referring to FIG. 3, in operation 340, an epitaxial layer can be formed in contact with the substrate and a second end of the multiple semiconductor layers. For example, as shown in FIG. 13, epitaxial layers 112 (e.g., epitaxial layers 112A and 112B) can be formed in contact with substrate 104 and the second end of semiconductor layers 438 and 108. In some embodiments, epitaxial layers 112 can be epitaxially grown on substrate 104, the first end of second set of semiconductor layers 108, and the second end of semiconductor layers 438 and 108. In some embodiments, epitaxial layers 112 can be epitaxially grown by (i) CVD, such as low pressure CVD (LPCVD), atomic layer CVD (ALCVD), ultrahigh vacuum CVD (UHVCVD), reduced pressure CVD (RPCVD), and other suitable CVD; (ii) molecular beam epitaxy (MBE) processes; (iii) any suitable epitaxial process; or (iv) a combination thereof. In some embodiments, epitaxial layer 112 can be conformally grown with precursors such as silane (SiH₄) and dichlorosilane (DCS) at a temperature from about 200° C. to about 600° C. under a pressure from about 5 Torr to about 300 Torr. As inner spacer structures 111 cover the first end of first set of semiconductor layers 438, epitaxial layer 112A can include a horizontal portion epitaxially grown on substrate 104 and a vertical portion epitaxially grown on second set of semiconductor layers 108 but not inner spacer structures 111 or the first set of semiconductor layers 438. On the second end of semiconductor layers 438 and 108, epitaxial layer 112B can include a horizontal portion epitaxially grown on substrate 104 and a vertical portion epitaxially grown on semiconductor layers 438 and 108.

In some embodiments, epitaxial layers 112 can include an epitaxially-grown semiconductor material, such as silicon. Epitaxial layers 112 can be un-doped or doped. In some embodiments, epitaxial layers 112 can include un-doped silicon. In some embodiments, epitaxial layers 112 can include silicon and can be in-situ doped during an epitaxial growth process using n-type dopants, such as phosphorus and arsenic. The n-type dopants can have a concentration from about 1×10¹⁹ atoms/cm³ to about 1×10²¹ atoms/cm³. In some embodiments, epitaxial layers 112 can include silicon and can be in-situ doped during an epitaxial growth process using p-type dopants, such as boron. The p-type dopants can have a concentration from about 1×10¹⁹ atoms/cm³ to about 1×10²¹ atoms/cm³.

In some embodiments, epitaxial layers 112 can have a thickness 112t ranging from about 1 nm to about 10 nm. A ratio of thickness 112t to thickness 108t can range from about 0.1 to about 2. If thickness 112t is less than about 1 nm or the ratio is less than about 0.1, first epitaxial layers 116B may not grow and subsequently-grown S/D structure 114B may be damaged during the formation of gate structures 110. If thickness 112t is greater than about 10 nm or the ratio is greater than about 2, the proximity between subsequently-formed S/D structure 114B and gate structures 110 may increase and the device on-current of nanostructure transistors 102-1 and 102-2 may decrease.

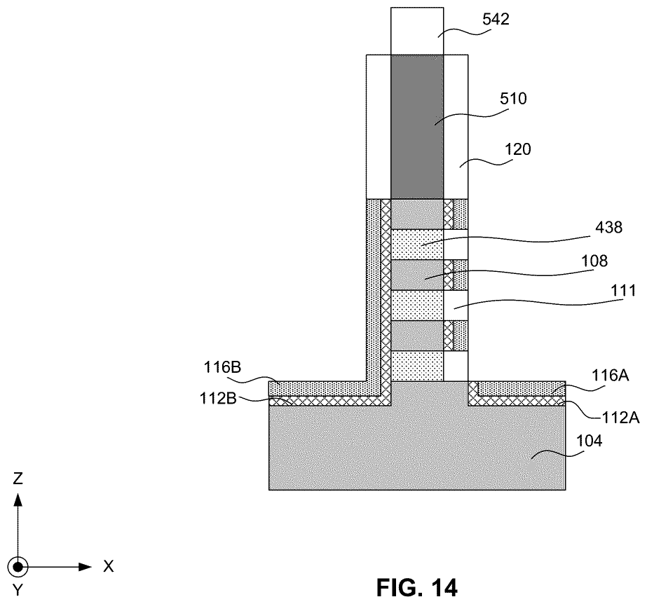

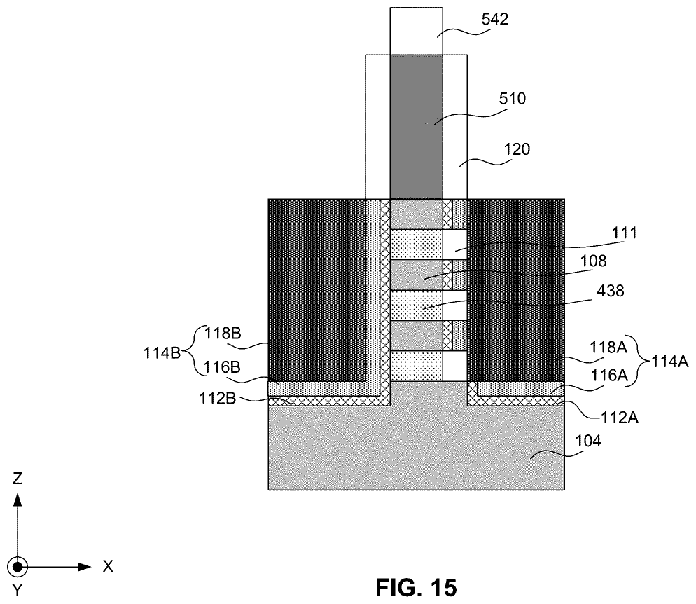

Referring to FIG. 3, in operation 350, a first S/D structure is formed in contact with the inner spacer structure and a second S/D structure is formed on the epitaxial layer. For example, as shown in FIGS. 14 and 15, first S/D structure 114A can be formed in contact with inner spacer structures 111 and second S/D structure 114B can be formed on epitaxial layer 112B. In some embodiments, the formation of S/D structures 114 can include formation of first S/D epitaxial layers 116 and formation of second S/D epitaxial layers 118.

In some embodiments, first and second S/D epitaxial layers 116 and 118 can be epitaxially grown by (i) CVD, such as LPCVD and other suitable CVD; (ii) MBE; (iii) any suitable epitaxial process; or (iv) a combination thereof. In some embodiments, first and second S/D epitaxial layers 116 and 118 can be grown by an epitaxial deposition/partial etch process, which can repeat the epitaxial deposition/partial etch process multiple times. Such repeated deposition/partial etch process can be referred to as a cyclic deposition-etch (CDE) process. The CDE process can reduce epitaxial defects formed during the growth and can control the profiles of S/D structures 114. In some embodiments, first and second S/D epitaxial layers 116 and 118 can be in-situ doped with n-type or p-type dopants during the epitaxial growth process.

In some embodiments, S/D structures 114 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, each of the multiple epitaxial layers of S/D structures 114 can have different dopant concentrations. For example, first S/D epitaxial layers 116 can include silicon doped with arsenide or phosphide at a concentration from about 1×10¹⁹ atoms/cm³ to about 1×10²¹ atoms/cm³. Second S/D epitaxial layers 118 can include silicon doped with phosphide at a concentration from about 1×10²¹ atoms/cm³ to about 1×10²² atoms/cm³.

In some embodiments, S/D structures 114 can include silicon, silicon germanium, germanium, or III-V materials (e.g., indium antimonide, or indium gallium antimonide) and can be in-situ doped during an epitaxial growth process using p-type dopants, such as boron, indium, and gallium. For p-type in-situ doping, p-type doping precursors, such as diborane, boron trifluoride, and other p-type doping precursors, can be used. In some embodiments, each of the multiple epitaxial layers of S/D structures 114 can have different compositions, for example, different dopant concentrations and/or different germanium concentrations. In some embodiments, first S/D epitaxial layers 116 can have a lower Ge concentration than second S/D epitaxial layers 118 to prevent lattice mismatch and dislocation defects. For example, first S/D epitaxial layers 116 can include silicon germanium having a germanium concentration from about 0% to about 30% and doped with boron at a concentration from about 1×10²⁰ atoms/cm³ to about 1×10²¹ atoms/cm³. Second S/D epitaxial layers 118 can include silicon germanium having a germanium concentration from about 20% to about 100% and doped with boron at a concentration from about 1×10²¹ atoms/cm³ to about 2×10²¹ atoms/cm³.

With epitaxial layer 112B on substrate 104 and the second end of semiconductor layers 438 and 108, S/D structure 114B can be epitaxially grown with reduced dislocation defects. S/D structure 114B can include first S/D epitaxial layers 116B and second S/D epitaxial layers 118B. In some embodiments, first and second S/D epitaxial layers 116B and 118B can include silicon and can be in-situ doped with n-type dopants having different concentrations. In some embodiments, first and second S/D epitaxial layers 116B and 118B can include silicon germanium with different germanium concentration and can be in-situ doped with p-type dopants having different concentrations. In some embodiments, epitaxial layer 112B can reduce the dislocation defects in S/D structure 114B by about 50% to about 80%. The decrease of the dislocation defects in S/D structure 114B can reduce the resistance of S/D structure 114B, increase the strain imparted on nanostructures 108, and increase the device on-current of nanostructure transistors 102-1 and 102-2.

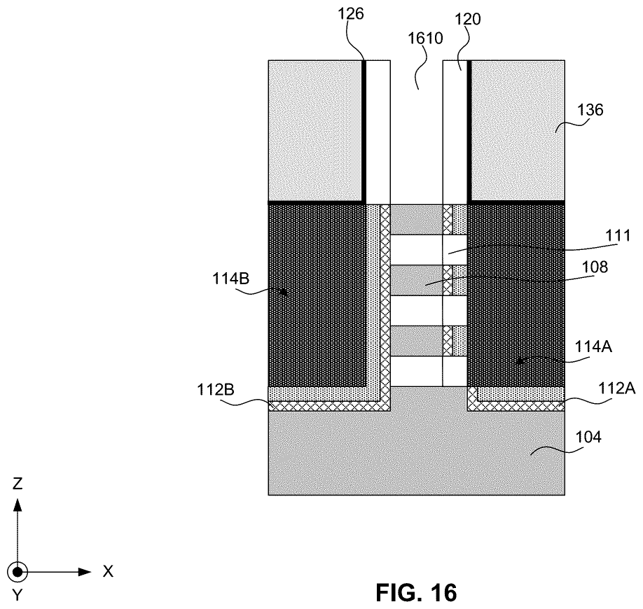

The formation of S/D structures 114 can be followed by the formation of ILD layer 136, as shown in FIG. 16. In some embodiments, ILD layer 136 can include a dielectric material deposited using a deposition method suitable for flowable dielectric materials. In some embodiments, the dielectric material can include silicon oxide.

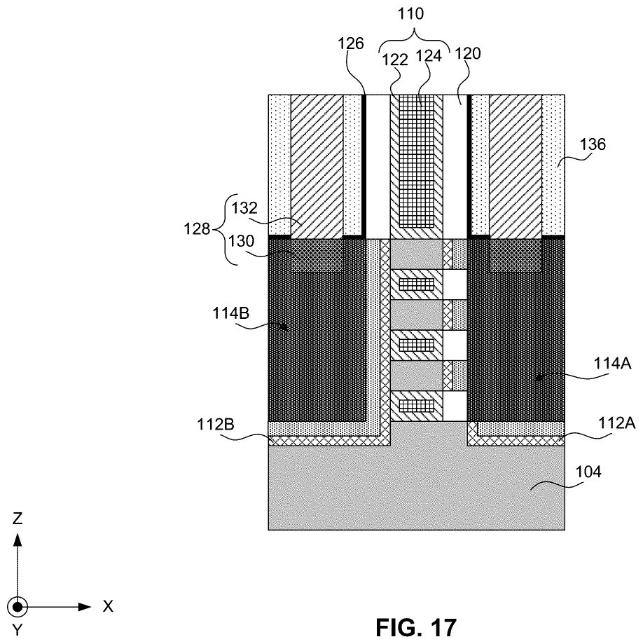

The formation of ILD layer 136 can be followed by formation of gate structures 110. For example, as shown in FIGS. 16 and 17, gate structures 110 can be formed wrapping around second set of semiconductor layers 108. In some embodiments, the formation of gate structures 110 can include removal of gate capping structure 542, sacrificial gate structures 510, and first set of semiconductor layers 438 as shown in FIG. 16, and deposition of gate dielectric layer 122 and metal gate structure 124 as shown in FIG. 17.

In some embodiments, gate capping structure 542 and sacrificial gate structures 510 can be removed in one or more etch processes. In some embodiments, the etch processes can include a dry etch process, a wet etch process, or other suitable etch processes to remove gate capping structure 542 and sacrificial gate structures 510 but not gate spacers 120. After the removal of gate capping structure 542 and sacrificial gate structures 510, first set of semiconductor layers 438 can be exposed for subsequent etching processes.

In some embodiments, first set of semiconductor layers 438 can be removed by a selective etching process. In some embodiments, first set of semiconductor layers 438 can have a higher etch selectivity than second set of semiconductor layers 108, gate spacers 120, epitaxial layers 112, and inner spacer structures 111. In some embodiments, due to the high etch selectivity, the selective etch process may not remove epitaxial layers 112, inner spacer structures 111, or second set of semiconductor layers 108 after removal of first set of semiconductor layers 438. Therefore, epitaxial layers 112B can protect S/D structure 114B and prevent damage to S/D structure 114B. Inner spacer structures 111 can protect S/D structure 114A and prevent damage to S/D structure 114A. After the selective etching process, first set of semiconductor layers 438 can be removed and openings 1610 can be formed above and around second set of semiconductor layers 108.

Referring to FIG. 17, gate structures 110 can be formed in openings 1610 and on the second set of semiconductor layers 108. Gate structures 110 can wrap around semiconductor layers 108 and can control the channel current flowing through semiconductor layers 108. In some embodiments, the formation of gate structures 110 can include the formation of gate dielectric layer 122 and the formation of metal gate structure 124.

In some embodiments, the formation of gate dielectric layer 122 can include formation of an interfacial layer on semiconductor layers 108 and formation of a high-k dielectric layer on the interfacial layer. The interfacial layer and high-k dielectric layer can wrap around each of semiconductor layers 108, as shown in FIG. 17. In some embodiments, the interfacial layer can include silicon oxide. In some embodiments, the high-k dielectric layer can include HfO₂, ZrO₂, or other suitable dielectric materials. In some embodiments, the formation of metal gate structure 124 can include formation of one or more work-function layers and formation of a gate electrode. Depending on the spaces between adjacent semiconductor layers 108, one or more work-function layers and the gate electrode can fill the spaces between adjacent semiconductor layers 108. After the formation of gate structures 110, as shown in FIG. 17, the end portion of the semiconductor layers 108 can be aligned with the first side (e.g., drain side) of gate structures 110 as a result of lateral etch of semiconductor layers 438 and 108 described above.

The formation of gate structures 110 can be followed by formation of S/D contact structures 128, as shown in FIG. 17. In some embodiments, the formation of S/D contact structures 128 can include etching through ILD layer 136 to expose S/D structures 114, formation of metal silicide layers 130 on exposed S/D structures 114, and formation of metal contacts 132 on metal silicide layers 130. Examples of metal used for forming metal silicide layers 130 can include cobalt, titanium, and nickel. In some embodiments, metal contacts 132 can include, for example, tungsten, cobalt, aluminum, copper, titanium, tantalum, silver, ruthenium, metal alloys, or combinations thereof. The formation of S/D contact structures 128 can be followed by formation of dielectric layers, formation of interconnects, and other processes, which are not described in detail for simplicity.

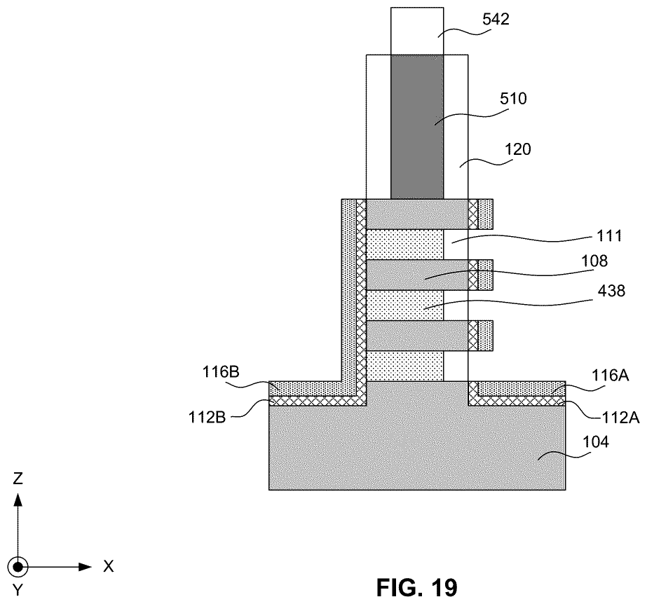

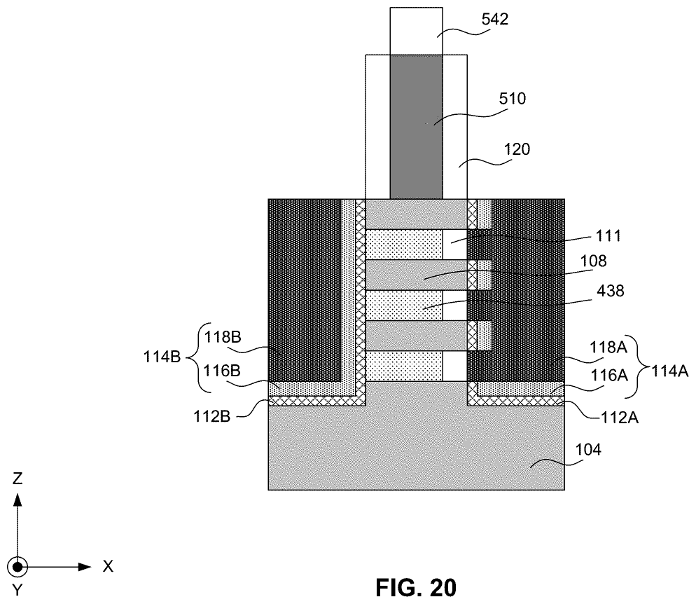

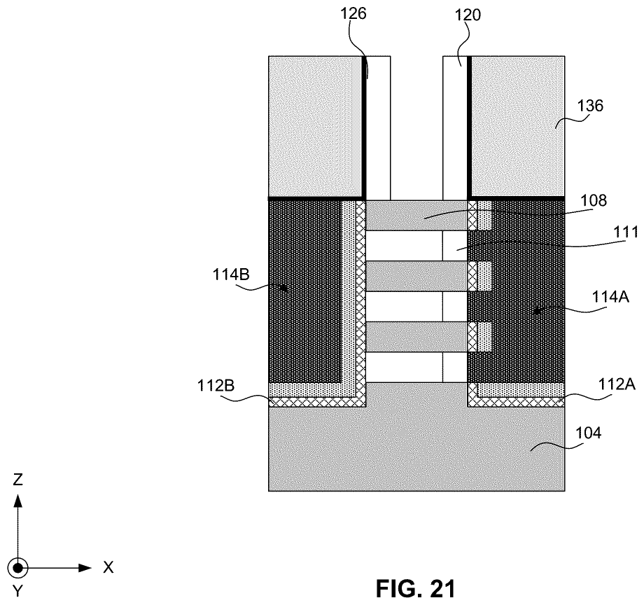

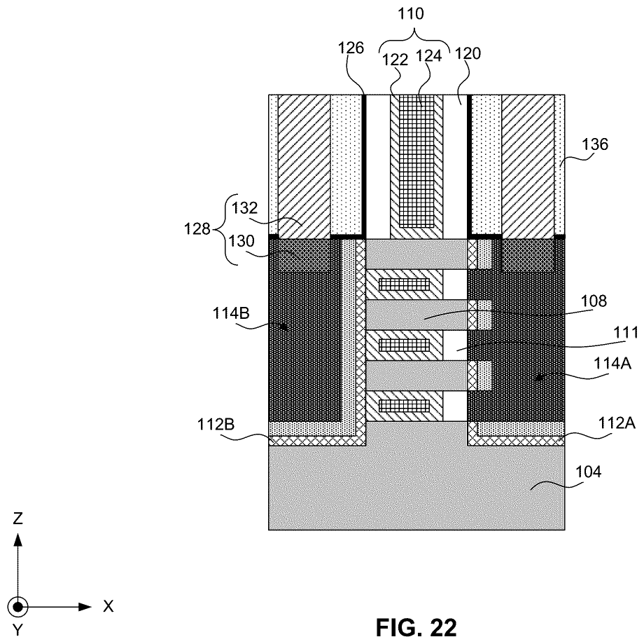

In some embodiments, FIGS. 18-22 illustrate cross-sectional views of semiconductor device 100 having another asymmetric S/D design. In some embodiments, after the formation of inner spacer structures 111 as shown in FIG. 11, epitaxial layers 112 can be formed on substrate 104 and semiconductor layers 438 and 108 without laterally etching semiconductor layers 438 and 108, as shown in FIG. 18. S/D structures 114 can be formed on epitaxial layers 112, as shown in FIGS. 19 and 20. Gate structures 110, ILD layer 136, and S/D contact structures 128 can be formed on semiconductor layers 108 and S/D structures 114 as shown in FIGS. 21 and 22. The processes to form epitaxial layers 112, S/D structures 114, gate structures 110, ILD layer 136, and S/D contact structures 128 are described above. In some embodiments, FIGS. 18-22 describes the fabrication process to form epitaxial layer 112, S/D structures 114, gate structures 110, ILD layer 136, and S/D contact structures 128 without laterally etching semiconductor layers 438 and 108. Because semiconductor layers 438 and 108 are not laterally etched in FIG. 18, the first end of the semiconductor layers 108 can be under gate spacer 120, as shown in FIGS. 18-22. In some embodiments, no lateral etching of semiconductor layers 438 and 108 can simplify the fabrication process of semiconductor device 100 and reduce the manufacturing cost. In some embodiments, no lateral etching of semiconductor layers 438 and 108 may increase the proximity between S/D structures 114 and gate structures 110 and decrease the device on-current of nanostructure transistors 102-1 and 102-2.

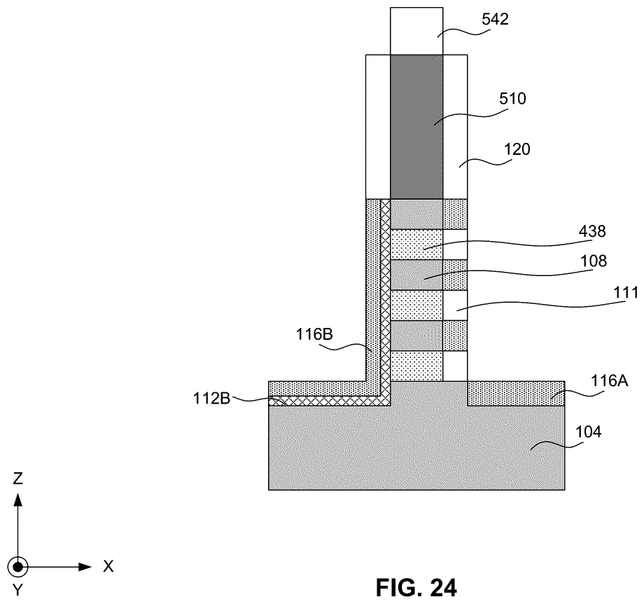

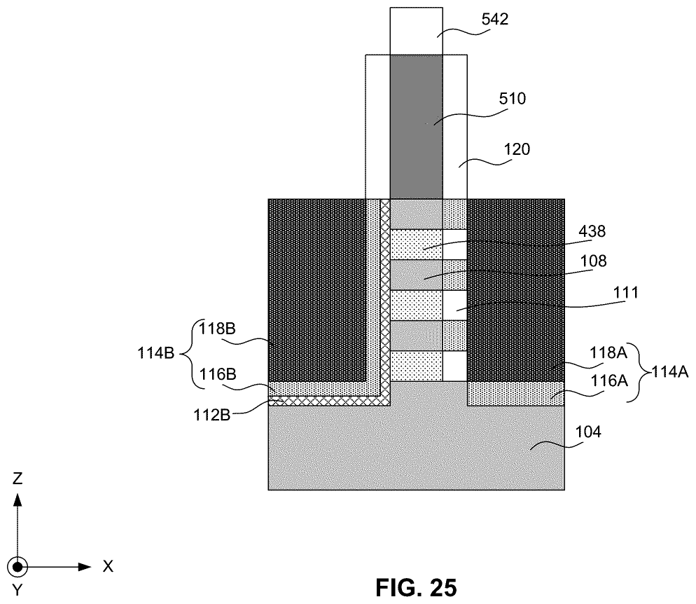

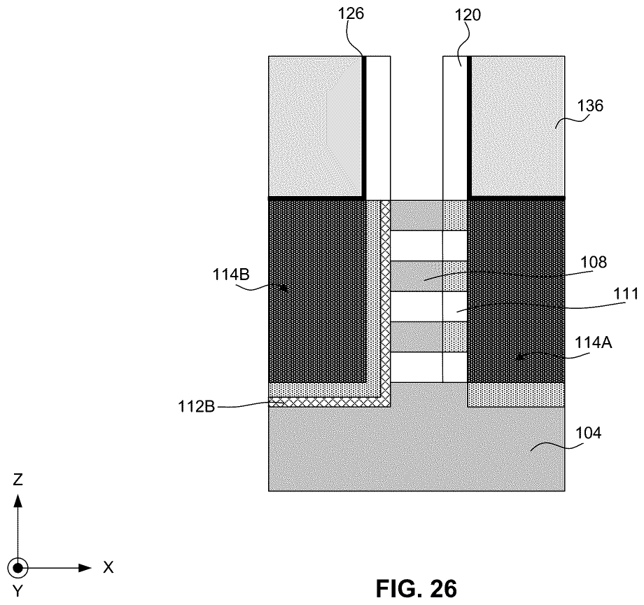

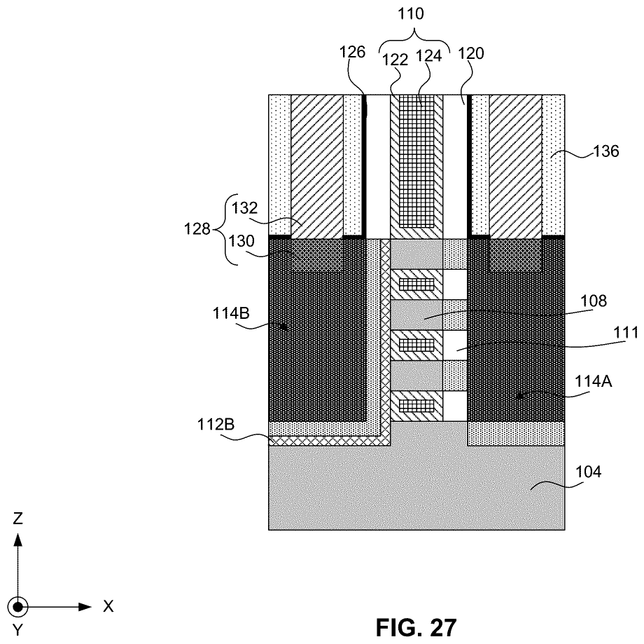

In some embodiments, FIGS. 23-27 illustrate cross-sectional views of semiconductor device 100 having yet another asymmetric S/D design. In some embodiments, after the lateral etching of semiconductor layers 438 and 108 as shown in FIG. 11, epitaxial layer 112B can be formed on one end (e.g., source side) of semiconductor layers 438 and 108, as shown in FIG. 23. In some embodiments, a mask layer can be patterned to cover the first end of semiconductor layers 438 and 108 in FIG. 23, and epitaxial layer 112B can be epitaxially grown on substrate 104 and the second end of semiconductor layers 438 and 108. S/D structures 114 can be formed on epitaxial layer 112B, semiconductor layers 108, and substrate 104 as shown in FIGS. 24 and 25. Gate structures 110, ILD layer 136, and S/D contact structures 128 can be formed on semiconductor layers 108 and S/D structures 114, as shown in FIGS. 26 and 27. The processes to form epitaxial layer 112B, S/D structures 114, gate structures 110, ILD layer 136, and S/D contact structures 128 are described above. In some embodiments, FIGS. 23-27 describes the fabrication process to form epitaxial layer 112, S/D structures 114, gate structures 110, ILD layer 136, and S/D contact structures 128 with epitaxial layer 112B on one end of semiconductor layers 438 and 108. In some embodiments, the formation of epitaxial layer 112B on one end of semiconductor layers 438 and 108 can reduce the proximity between S/D structure 114A and gate structures 110 and decrease the device on-current of nanostructure transistors 102-1 and 102-2. In some embodiments, the formation of epitaxial layer 112B on one end of semiconductor layers 438 and 108 can increase the complexity of the fabrication process of semiconductor device 100 and thus increase the manufacturing cost.

Various embodiments in the present disclosure provide example methods for forming an asymmetric S/D design for semiconductor device 100. Semiconductor device 100 can have nanostructures 108 acting as channels and gate structures 110 wrapped around nanostructures 108. Inner spacer structures 111 can be in contact with a first side (e.g., drain side) of gate structure 110 and can be disposed between gate structures 110 and S/D structure 114A. Epitaxial layer 112B can be in contact with a second side (e.g., source side) of gate structures 110 and can be disposed between gate structures 110 and S/D structure 114B. The second side can be opposite to the first side. With epitaxial layer 112B on the source side, the dislocation defects in S/D structure 114B can be reduced by about 50% to about 80%, the resistance of S/D structure 114B can be significantly reduced, the proximity between S/D structure 114B and gate structures 110 can be reduced, the strain imparted on nanostructure 108 can be improved, and the device current of semiconductor device 100 can be increased. Additionally, inner spacer structures 111 on the drain side can reduce the parasitic capacitance between gate structures 110 and S/D structure 114A. The asymmetric S/D design can improve the device performance of semiconductor device 100, for example, by about 5% to about 20% for a p-type nanostructure transistor device and by about 0.5% to about 5% for an n-type nanostructure transistor device.

In some embodiments, a semiconductor structure includes multiple semiconductor layers on a substrate, a gate structure wrapped around the multiple semiconductor layers, an inner spacer structure between the multiple semiconductor layers and in contact with a first side of the gate structure, and an epitaxial layer in contact with a second side of the gate structure. The second side is opposite to the first side.

In some embodiments, a semiconductor device includes multiple channel structures on a substrate, a gate structure wrapped around the multiple channel structures, an inner spacer structure in contact with the gate structure and adjacent to a first end of the multiple channel structures, a gate spacer on a sidewall of the gate structure and above the multiple channel structures, and an epitaxial layer in contact with the gate structure and a second end of the multiple semiconductor layers. The second end is opposite to the first end.

In some embodiments, a method includes forming multiple semiconductor layers on a substrate. The multiple semiconductor layers include a first set of semiconductor layers and a second set of semiconductor layers stacked in an alternate configuration. The method further includes replacing a portion of the first set of semiconductor layers with an inner spacer structure at a first end of the multiple semiconductor layers, forming an epitaxial layer in contact with the substrate and a second end of the multiple semiconductor layers, and forming a first S/D structure in contact with the inner spacer structure and a second S/D structure on the epitaxial layer. The second end is opposite to the first end.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of semiconductor layers on a substrate;
a gate structure wrapped around the plurality of semiconductor layers;
an inner spacer structure between the plurality of semiconductor layers and in contact with a first side of the gate structure; and
an epitaxial layer in contact with a second side of the gate structure, wherein the second side is opposite to the first side.

2. The semiconductor structure of claim 1, wherein the epitaxial layer is in contact with the substrate.

3. The semiconductor structure of claim 1, further comprising a source/drain (S/D) structure in contact with the epitaxial layer.

4. The semiconductor structure of claim 1, further comprising:
an additional epitaxial layer in contact with the plurality of semiconductor layers and the inner spacer structure; and
a S/D structure in contact with the additional epitaxial layer and the inner spacer structure.

5. The semiconductor structure of claim 1, further comprising:
a first S/D structure in contact with the inner spacer structure and the plurality of semiconductor layers; and
a second S/D structure in contact with the epitaxial layer.

6. The semiconductor structure of claim 1, wherein the inner spacer structure is wrapped around an end portion of the plurality of semiconductor layers.

7. The semiconductor structure of claim 1, wherein an end portion of the plurality of semiconductor layers is aligned with the first side of the gate structure.

8. The semiconductor structure of claim 1, wherein the epitaxial layer comprises a silicon epitaxial layer doped with a dopant.

9. The semiconductor structure of claim 1, wherein the epitaxial layer has a thickness ranging from about 1 nm to about 10 nm.

10. A semiconductor device, comprising:
a plurality of channel structures on a substrate;
a gate structure wrapped around the plurality of channel structures;
an inner spacer structure in contact with the gate structure and adjacent to a first end of the plurality of channel structures;
a gate spacer on a sidewall of the gate structure and above the plurality of channel structures; and
an epitaxial layer in contact with the gate structure and a second end of the plurality of channel structures, wherein the second end is opposite to the first end.

11. The semiconductor device of claim 10, wherein the epitaxial layer comprises a vertical portion in contact with the gate structure and the plurality of channel structures and a horizontal portion in contact with the substrate.

12. The semiconductor device of claim 10, further comprising a source/drain (S/D) structure in contact with the epitaxial layer.

13. The semiconductor device of claim 10, further comprising:
an additional epitaxial layer in contact with the first end of the plurality of channel structures; and
a S/D structure in contact with the additional epitaxial layer and the inner spacer structure.

14. The semiconductor device of claim 10, further comprising:
a first S/D structure in contact with the inner spacer structure and the first end of the plurality of semiconductor layers; and
a second S/D structure in contact with the epitaxial layer.

15. The semiconductor device of claim 10, wherein the first end of the plurality of channel structures is under the gate spacer.

16. A method, comprising:
forming a plurality of semiconductor layers on a substrate, wherein the plurality of semiconductor layers comprise a first set of semiconductor layers and a second set of semiconductor layers stacked in an alternate configuration;
replacing a portion of the first set of semiconductor layers with an inner spacer structure at a first end of the plurality of semiconductor layers;
forming an epitaxial layer in contact with the substrate and a second end of the plurality of semiconductor layers, wherein the second end is opposite to the first end; and
forming a first S/D structure in contact with the inner spacer structure and a second S/D structure on the epitaxial layer.

17. The method of claim 16, further comprising replacing the first set of semiconductor layers with a gate structure, wherein the gate structure is wrapped around the second set of semiconductor layers and in contact with the inner spacer structure and the epitaxial layer.

18. The method of claim 16, wherein replacing the portion of the first set of semiconductor layers with the inner spacer structure comprises:
covering the second end of the plurality of semiconductor layers with a mask layer;
laterally etching the portion of the first set of semiconductor layers;
depositing a spacer layer on the first end of the plurality of semiconductor layers; and
removing the spacer layer from the second set of semiconductor layers.

19. The method of claim 16, wherein forming the epitaxial layer comprises:
laterally etching the plurality of semiconductor layers; and
epitaxially growing a silicon layer on the substrate and the plurality of semiconductor layers.

20. The method of claim 16, wherein forming the epitaxial layer comprises:
laterally etching the first and second sets of semiconductor layers;
covering the first end of the plurality of semiconductor layers with a mask layer; and
epitaxially growing a silicon layer on the substrate and the second end of the plurality of semiconductor layers.
